(19) United States
(12) Patent Application Publication
(10) Pub. No.: US 2014/0231941 A1
(43) Pub. Date: Aug. 21, 2014

(54) MAGNETORESISTIVE STRUCTURES, MEMORY DEVICES INCLUDING THE SAME, AND METHODS OF MANUFACTURING THE MAGNETORESISTIVE STRUCTURES AND THE MEMORY DEVICES

(71) Applicants: Sung-chul LEE, Osan-si (KR); Kwang-seok KIM, Seoul (KR); Kee-won KIM, Suwon-si (KR); Young-man JANG, Hwaseong-si (KR); Ung-hwan PI, Seoul (KR)

(72) Inventors: Sung-chul LEE, Osan-si (KR); Kwang-seok KIM, Seoul (KR); Kee-won KIM, Suwon-si (KR); Young-man JANG, Hwaseong-si (KR); Ung-hwan PI, Seoul (KR)

(21) Appl. No.: 14/182,660

(22) Filed: Feb. 18, 2014

(30) Foreign Application Priority Data
Feb. 19, 2013 (KR) 10-2013-0017662

(51) Int. Cl. H01L 43/02

(52) U.S. Cl. CPC H01L 43/02; B82Y 10/00
USPC 257/421; 977/935

(57) ABSTRACT

Magnetoresistive structures, memory devices including the same, and methods of manufacturing the magnetoresistive structures and the memory devices, include a plurality of free layers each having a magnetization direction that is changeable, a separation layer covering at least two of the plurality of free layers, and at least one pinned layer opposing the plurality of free layers. The separation layer is between the at least one pinned layer and the plurality of free layers. The at least one pinned layer has a magnetization direction that is fixed.

### CROSS-REFERENCE TO RELATED APPLICATIONS

This application claims the benefit of priority under 35 U.S.C. §119 from Korean Patent Application No. 10-2013-0017662, filed on Feb. 19, 2013, in the Korean Intellectual Property Office, the disclosure of which is incorporated herein by reference in its entirety.

### BACKGROUND

1.Field

Example embodiments of the inventive concept relate to magnetoresistive structures, memory devices including the same, and/or methods of manufacturing the magnetoresistive structures and the memory devices.

2. Discussion of Related Art

Magnetic random access memory (MRAM) is a memory technology to store data by using the resistance variation of a magnetoresistive element such as a magnetic tunneling junction (MTJ) element. The resistance of the MTJ element varies according to the magnetization direction of a free layer. In other words, when the magnetization direction of a free layer is identical to that of a pinned layer, the MTJ element has a low resistance. When the magnetization direction of the free layer is opposite to that of the pinned layer, the MTJ element has a high resistance. If the MTJ element has a low resistance, data may correspond to ‘0’. On the other hand, if the MTJ element has a high resistance, data may correspond to ‘1’. MRAM has drawn attention as one of the next-generation non-volatile memory devices due to non-volatility, high-speed operation, and high endurance.

To increase the recording density of the MRAM (i.e., to implement high density MRAM), a size of the MTJ element should be reduced. However, if a width of the MTJ element is reduced to be equal to or lower than several tens of nanometers (nm), a problem due to an etch damage of the MTJ element increases, and thus, the characteristics and uniformity of the MRAM may deteriorate. Further, if the size of the MTJ element is reduced, a volume of the pinned layer is reduced too, which makes it difficult to obtain thermal stability of the pinned layer. In addition, other diverse problems may occur due to this cause.

### SUMMARY

Example embodiments of the inventive concepts provide magnetoresistive structures having excellent performance and memory devices including the magnetoresistive structures.

Example embodiments of the inventive concepts also provide magnetoresistive structures that have high integration (high density) and memory devices including the magnetoresistive structures.

Example embodiments of the inventive concepts also provide magnetoresistive structures capable of preventing and overcoming a problem due to an etch damage and memory devices including the magnetoresistive structures.

Example embodiments of the inventive concepts also provide magnetoresistive structures having a pinned layer with excellent thermal stability and memory devices including the magnetoresistive structures.

Example embodiments of the inventive concepts also provide methods of manufacturing the magnetoresistive structures and the memory devices.

According to some example embodiments of the inventive concepts, there is provided a magnetoresistive structure including a plurality of free layers each having a magnetization direction that is changeable, a separation layer covering at least two of the plurality of free layers; and at least one pinned layer opposing the plurality of free layers, the separation layer being between the magnetization pinned layer and the plurality of magnetization free layers, and the at least one pinned layer has a magnetization direction that is fixed.

Both side surfaces of the separation layer may be spaced apart from the plurality of free layers.

The separation layer may have a structure extending from both sides of the plurality of free layers.

The separation layer may be on the plurality of free layers, and wherein the at least one pinned layer is on the separation layer.

The separation layer and the at least one pinned layer may have a same plane structure.

The plurality of free layers and the at least one pinned layer may have perpendicular magnetic anisotropy.

The plurality of free layers and the at least one pinned layer may have in-plane magnetic anisotropy.

Each of the plurality of free layers may include a horizontal element and at least one vertical element extending from the horizontal element.

Each of the plurality of free layers may further include a protruding element on both ends.

A plurality of separation layers may be provided, and spaced apart from each other in plan view, and at least two of the plurality of free layers may correspond to a respective one of the plurality of separation layers.

A plurality of pinned layers may be provided, and spaced apart from each other, and at least two of the plurality of free layers may correspond to a respective one of the plurality of pinned layers.

According to other example embodiments of the inventive concepts, there is provided a memory device including the magnetoresistive structure.

The memory device may further include a switching element connected to each of the plurality of free layers.

The memory device may be magnetic random access memory (MRAM).

The memory device may be spin transfer torque magnetic random access memory (STT-MRAM).

According to further example embodiments of the inventive concepts, there is provided a magnetoresistive structure including a plurality of free layers each having a magnetization direction that is changeable, a pinned layer shared by at least two of the plurality of free layers, wherein the pinned layer has a magnetization direction that is fixed, and at least one separation layer between the plurality of free layers and the pinned layer.

The magnetoresistive structure may have a top-pinned structure in which the pinned layer is above the plurality of free layers.

The plurality of free layers and the pinned layer may have perpendicular magnetic anisotropy.

The plurality of free layers and the pinned layer may have in-plane magnetic anisotropy.

According to yet still other example embodiments of the inventive concepts, there is provided a memory device including the magnetoresistive structure.

The memory device may further include a switching element connected to each of the plurality of free layers.

The memory device may be magnetic random access memory (MRAM).

The memory device may be spin transfer torque magnetic random access memory (STT-MRAM).

According to still further example embodiments of the inventive concepts, there is provided a magnetoresistive structure including a free layer having a magnetization direction that is changeable, a separation layer on the free layer and having a greater width than a width of the free layer; and a pinned layer on the free layer and having a greater width than a width of the free layer, the pinned layer having a magnetization direction that is fixed.

The magnetoresistive structure may include a plurality of free layers.

The separation layer and/or the pinned layer may form a stacked structure covering the plurality of free layers.

The plurality of free layers and the pinned layer may have perpendicular magnetic anisotropy.

The plurality of free layers and the pinned layer may have in-plane magnetic anisotropy.

According to still other example embodiments, a magnetoresistive structure, including a stacked structure including a separation layer and a pinned layer, sequentially stacked, and a plurality of free layers under the stacked structure. The plurality of free layers are each electrically connected to the pinned layer via the separation layer. The pinned layer has a magnetization direction that is fixed, and the plurality of free layers each have a magnetization direction that is changeable.

The plurality of free layers and the pinned layer may have a same magnetic anisotropy.

Each of the plurality of free layers may have a main body and at least one protrusion protruding from the main body. The at least one protrusion may protrude either upward or downward in a direction perpendicular to an upper surface of the main body.

Both ends of the stacked structure may project beyond ends of the plurality of free layers in a direction parallel with an upper surface of the plurality of free layers.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view of a memory device including a magnetoresistive structure according to some example embodiments of the inventive concepts;

FIG. 2 is a cross-sectional view of a magnetoresistive structure having perpendicular magnetic anisotropy according to some example embodiments of the inventive concepts;

FIG. 3 is a cross-sectional view of a magnetoresistive structure having in-plane magnetic anisotropy according to other example embodiments of the inventive concepts;

FIG. 4 is a cross-sectional view of a magnetoresistive structure according to yet other example embodiments of the inventive concepts;

FIGS. 5 and 6 are plan views of magnetoresistive structure arrays according to further example embodiments of the inventive concepts;

FIG. 7 is a cross-sectional view of a magnetoresistive structure according to still other example embodiments of the inventive concepts;

FIG. 8 is a cross-sectional view of a magnetoresistive structure according to still further example embodiments of the inventive concepts; and

FIGS. 9A through 9G are cross-sectional views for explaining a method of manufacturing a memory device including a magnetoresistive structure according to some example embodiments of the inventive concepts.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto.

Hereinafter, magnetoresistive structures, memory devices including the same, and methods of manufacturing the magnetoresistive structures and the memory devices according to example embodiments of the inventive concepts will be described with reference to drawings.

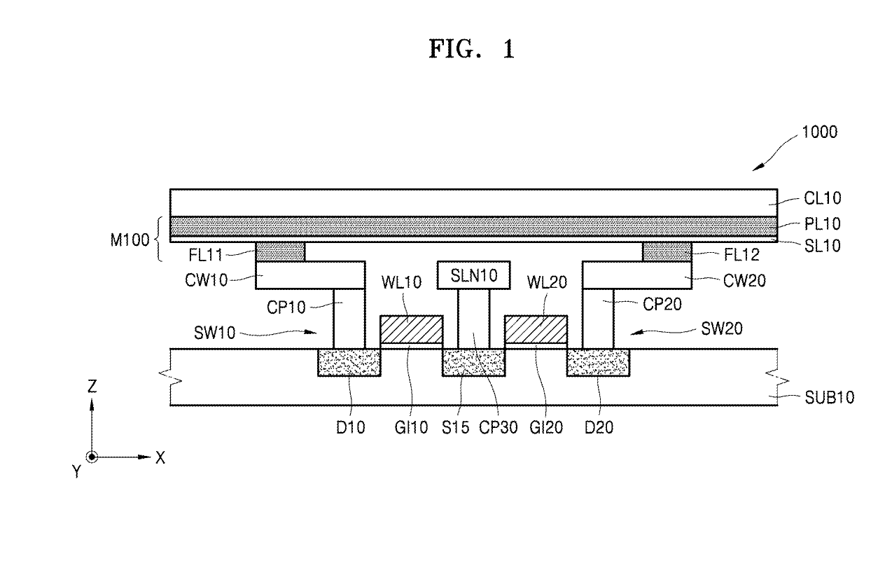

FIG. 1 is a cross-sectional view of a memory device including a magnetoresistive structure according to some example embodiments of the inventive concepts.

Referring to FIG. 1, a magnetoresistive structure M100 of a memory device 1000 may include a plurality of magnetization free layers (hereinafter referred to as “free layers”). For example, the free layers may include a first free layer FL11 and a second free layer FL12. The first free layer FL11 and the second free layer FL12 may be arranged to be spaced apart from each other in a horizontal direction (for example, an X-axis direction). The magnetoresistive structure M100 may include a separation layer SL10 covering the free layers FL11 and FL12. The magnetoresistive structure M100 may also include a magnetization pinned layer (hereinafter referred to as “a pinned layer”) PL10 opposing the free layers FL11 and FL12 having the separation layer SL10 disposed therebetween. The pinned layer PL10 may be a layer shared by the free layers FL11 and FL12.

The free layers FL11 and FL12 are magnetic layers that have a changeable magnetization direction and may be formed of a ferromagnetic material. The ferromagnetic material may include at least one of Co, Fe, and Ni, and may further include another element, for example, B, Cr, Pt, Pd, etc. Each of the free layers FL11 and FL12 may have a thickness in a range from about 0.5 nm to about 15 nm, for example, in a range from about 1 nm to about 10 nm. The pinned layer PL10 is a magnetic layer that has a pinned magnetization direction and may be formed of a ferromagnetic material including at least one of Co, Fe, and Ni. The ferromagnetic material may further include another element, for example, B, Cr, Pt, Pd, etc. besides Co, Fe, and Ni. The free layers FL11 and FL12 and the pinned layer PL10 may be formed of the same material or different materials. The pinned layer PL10 may have a thickness approximately 15 nm or less, for example.

The free layers FL11 and FL12 and the pinned layer PL10 each may have a perpendicular magnetic anisotropy. In this case, the free layers FL11 and FL12 and/or the pinned layer PL10 may include a Co-based material or a Fe-based material, and may include a single-layered or a multi-layered structure. For example, the free layers FL11 and FL12 and/or the pinned layer PL10 may include at least one selected from the group consisting of Co, CoFe, CoFeB, CoCr, and CoCrPt, or may have a multi-layered structure in which a first layer formed of at least one of Co, Fe, Co alloy, and Fe alloy and a second layer formed of at least one of Pt, Ni, and Pd are alternately stacked. The multi-layered structure may include, for example, a [Co/Pd]ₙ structure, a [Co/Ni]ₙ structure, a [Co/Pt]ₙ structure, or a [Fe/Pd]ₙ structure, etc. Regarding the [Co/Pd]ₙ structure, ‘n’ is the number of repeating stacks of Co and Pd, wherein Co and Pd are alternately stacked. Regarding the [Co/Ni]ₙ, [Co/Pt]ₙ, and [Fe/Pd]ₙ structures, ‘n’ has the same meaning as described above. The free layers FL11 and FL12 and the pinned layer PL10 may include a FePt layer or a CoPt layer having a L1ₒ structure or an alloy layer of a rare-earth element and a transition metal. The rare-earth element may be at least one of Tb and Gd. The transition metal may be at least one of Ni, Fe, and Co. However, the materials for forming the free layers FL11 and FL12 and the pinned layer PL10 are merely examples, and thus, other various materials may be used to form the free layers FL11 and FL12 and the pinned layer PL10.

The free layers FL11 and FL12 and the pinned layer PL10 each may have in-plane magnetic anisotropy. If the free layers FL11 and FL12 and the pinned layer PL10 each have in-plane magnetic anisotropy, the free layers FL11 and FL12 and the pinned layer PL10 may be formed of a soft magnetic material. A magnetic anisotropy energy of the soft magnetic material may be, for example, in the range of about 10⁴ and about 10⁵ erg/cc. The soft magnetic material may be, for example, Ni, Co, NiCo, NiFe, CoFe, CoFeB, CoZrNb, or CoZrCr, etc. If the free layers FL11 and FL12 and the pinned layer PL10 each have in-plane magnetic anisotropy, a magnetic easy axis of each of the free layers FL11 and FL12 and the pinned layer PL10 may be determined according to shape anisotropy. In this connection, the free layers FL11 and FL12 may have a long shape in a set (or, predetermined) direction, for example, the X-axis direction. For example, the free layers FL11 and FL12 each may have a rectangular shape having a long face in the X-axis direction and a short face in a Y-axis direction. Alternatively, the free layers FL11 and FL12 may each have an oval shape or a shape similar to the oval shape.

The separation layer SL10 may be formed of an insulating material. For example, the separation layer SL10 may include an insulating oxide, such as, a magnesium oxide and an aluminum oxide. When the separation layer SL10 is formed of an insulating material, the magnetoresistive element M100 may be a magnetic tunneling junction (MTJ) element. However, the material for the separation layer SL10 is not limited to these materials. In some cases, the separation layer SL10 may be formed of a conductive material. In this case, the separation layer SL10 may include at least one conductive material (metal) selected from the group consisting of Ru, Cu, Al, Au, Ag, and a mixture of these materials. The separation layer SL10 may have a thickness of approximately 5 nm or less, for example, approximately 3 nm or less. The separation layer SL10 may be a tunnel layer or a barrier layer.

Both side surfaces (etching surfaces) of the separation layer SL10 may be spaced apart from the free layers FL11 and FL12. Both side surfaces of the separation layer SL10 may be side surfaces with respect to the X-axis direction. Also, the separation layer SL10 may have a structure extending in both sides (with respect to the X-axis direction) of the free layers FL11 and FL12. The pinned layer PL10 may have the same (or almost similar) structure as the separation layer SL10. In other words, when viewed from above, the pinned layer PL10 and the separation layer SL10 may have the same (or almost similar) structure.

The separation layer SL10 may be disposed on the plurality of free layers FL11 and FL12, and the pinned layer PL10 may be disposed on the separation layer SL10. In other words, the magnetoresistive structure M100 may have a top-pinned structure in which the pinned layer PL10 is disposed above the plurality of free layers FL11 and FL12.

In addition, the pinned layer PL10 may have a synthetic antiferromagnetic (SAF) structure. In this case, the pinned layer PL10 may include a lower pinned layer, an upper pinned layer, and a spacer disposed therebetween, which may form the SAF structure. In the SAF structure, two pinned layers (the lower and upper pinned layers) disposed adjacent to each other and having the spacer therebetween may have opposite pinned magnetization directions. Materials of the lower and upper pinned layers may be identical or similar to each other. The spacer may include a conductive material, for example, at least one of Ru, Cu, Al, Au, Ag, and a mixture of these materials, and may have a thickness of approximately 5 nm or less, for example, approximately 3 nm or less.

The first free layer FL11, a region of the separation layer SL10, and a region of the pinned layer PL10 that correspond to the first free layer FL11 may form a “first cell region” in the magnetoresistive structure M100. Similarly to this, the second free layer FL12, a region of the separation layer SL10, and a region of the pinned layer PL10 that correspond to the second free layer FL12 may form a “second cell region” in the magnetoresistive structure M100.

The memory device 1000 may further include a plurality of switching elements SW10 and SW20 electrically connected to the free layers FL11 and FL12, respectively. For example, the plurality of switching elements SW10 and SW20 may include the first switching element SW10 connected to the first free layer FL11 and the second switching element SW20 connected to the second free layer FL12. The plurality of switching elements SW10 and SW20 may be transistors. In this case, the first switching element SW10 may include a first drain region D10 and a common source region S15 that are included in a substrate SUB10 and a first word line WL10 provided on the substrate SUB 10 between the first drain region D10 and the common source region S15. The first word line WL10 may be referred to as ‘a gate line’. The first switching element SW10 may further include a first gate insulating layer GI10 provided between the first word line WL10 and the substrate SUB10. The second switching element SW20 may include a second drain region D20 and the common source region S15 that are included in the substrate SUB10 and a second word line WL20 provided on the substrate SUB10 between the second drain region D20 and the common source region S15. The second switching element SW20 may further include a second gate insulating layer GI20 provided between the second word line WL20 and the substrate SUB10. The common source region S15 may be provided between the first drain region D10 and the second drain region D20. The first switching element SW10 and the second switching element SW20 may share the common source region S15. Functions of the first drain region D10 and the common source region S15 may be switched. Similarly, functions of the second drain region D20 and the common source region S15 may also be switched. The structures of the first switching element SW10 and the second switching element SW20 are exemplary, and may be modified in various ways. For example, the switching element SW10 and the second switching element SW20 may not share the common source region S15 and may include separate source regions.

The first drain region D10 may be electrically connected to the first free layer FL11. The second drain region D20 may be electrically connected to the second free layer FL12. The first drain region D10 and the first free layer FL11 may be electrically connected to each other via a first contact plug CP10 and a first connection wire CW10. The second drain region D20 and the second free layer FL12 may be electrically connected to each other via a second contact plug CP20 and a second connection wire CW20. A source line SLN10 connected to the common source region S15 may be provided. The common source region S15 and the source line SLN10 may be connected to each other via a third contact plug CP30. The connection structures between the switching elements SW10 and SW20 and the magnetoresistive element M100 are examples and may be modified in various forms. For example, the first free layer FL11 may be disposed on the first contact plug CP10 without using the first connection wire CW10. Similarly, the second free layer FL12 may be disposed on the second contact plug CP20 without using the second connection wire CW20. Other diverse modification structures may be possible.

A capping layer CL10 may be provided on the pinned layer PL10. The capping layer CL10 may be a layer for protecting the pinned layer PL10 that is a magnetic layer. The capping layer CL10 may be formed of a non-magnetic material, for example, a metal. The capping layer CL10 may have a plane structure that is the same as, or similar to, the pinned layer PL10. The pinned layer PL10 may be used as a bit line, or a stack structure of the pinned layer PL10 and the capping layer CL10 may be used as a bit line or a word line. However, in some cases, a separate bit line (not shown) may be provided on the capping layer CL10.

Although the plurality of free layers FL11 and FL12 are separated into cell units in the present example embodiments, the separation layer SL10 and the pinned layer PL10 are not separated into cell units and have a large size that covers the plurality of free layers FL11 and FL12. In this case, problems such as characteristic deterioration of a magnetoresistive element and non-uniformity of a magnetoresistance ratio (i.e., MR ratio) due to an etch damage of the separation layer SL10 may be prevented. Also, a volume of the pinned layer PL10 is increased, and thus, a thermal stability of the pinned layer PL10 may be greatly improved. Further, a switching asymmetry problem of the plurality of free layers FL11 and FL12 due to a stray field of the pinned layer PL10 may be suppressed/prevented. If the pinned layer PL10 has a relatively larger size than the plurality of free layers FL11 and FL12, an influence of the stray field of the pinned layer PL10 on the plurality of free layers FL11 and FL12 may be reduced. In particular, if the pinned layer PL10 has the SAF structure, the greater the size of the pinned layer PL10, the easier the stray field may be offset. On the grounds stated above, according to the present example embodiments, the performance, uniformity, reliability, etc. of the memory device 1000 may be improved, and a recording density thereof may be increased.

A conventional MTJ element is used to deposit a free layer, a barrier layer, and a pinned layer, and separate the deposited free layer, barrier layer, and pinned layer into cell units by patterning (etching). Thus, the free layer, the barrier layer, and the pinned layer may have the same plane (or almost the same) structure in an MTJ cell, and side surfaces (etch surfaces) thereof may be present on the same (or almost the same) perpendicular line. In this case, a side surface etch damage of the MTJ cell influences an R·A (resistance×area) distribution thereof and an MR ratio distribution. The smaller the size of the MTJ cell, the greater the influence of the side surface etch damage. Thus, a problem caused by the side surface etch damage is a factor that hinders the implementation of a high density magnetic random access memory (MRAM). Further, the smaller the size of the MTJ cell, the smaller the volume of the pinned layer, which makes it difficult to obtain the thermal stability of the pinned layer. Also, as the size of the MTJ cell is smaller, the switching asymmetry problem of the free layer due to the stray field that occurs in the pinned layer is more severe. These problems may be also factors that hinder the implementation of the high density MRAM.

In the present example embodiments, after the plurality of free layers FL11 and FL12 are formed in cell units, the separation layer SL10 and the pinned layer PL10 are not separated into cell units and have the large size that covers the plurality of free layers FL11 and FL12. Thus, as described above, the problems of the conventional MTJ cell may be prevented or minimized. That is, the problem due to the etch damage of the separation layer SL10 may be fundamentally prevented, the thermal stability of the pinned layer PL10 may be greatly increased, and the switching asymmetry problem due to the stray field may be suppressed. In this connection, the high density MRAM may be easily implemented. Furthermore, an MRAM having excellent performance and improved uniformity, reliability, stability, etc. may be implemented.

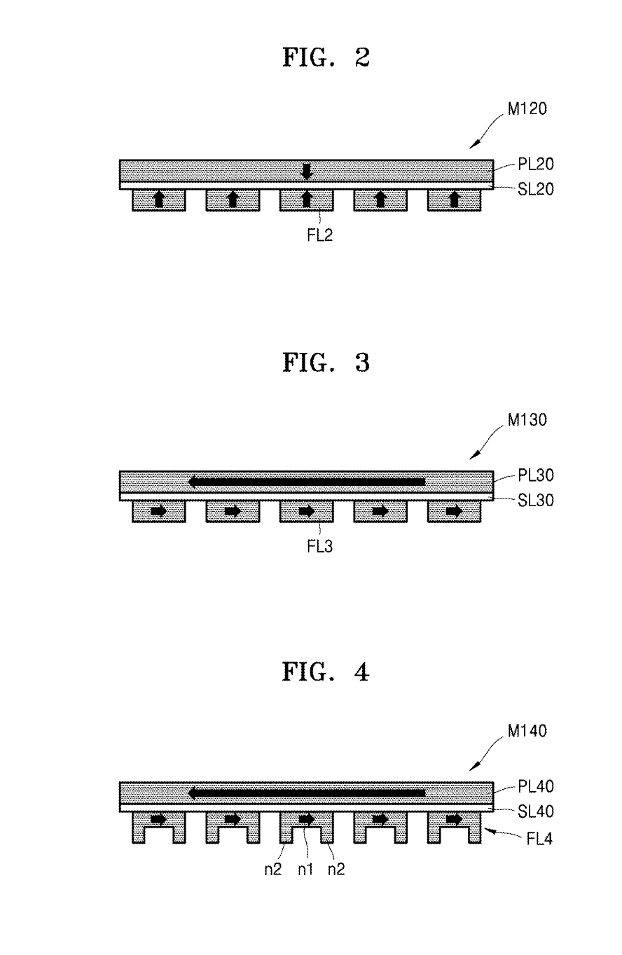

FIG. 2 is a cross-sectional view of a magnetoresistive structure having perpendicular magnetic anisotropy according to some example embodiments of the present inventive concepts.

Referring to FIG. 2, a magnetoresistive structure M120 may include a plurality of free layers FL2 and a separation layer SL20 and a pinned layer PL20 that cover the plurality of free layers FL2. The plurality of free layers FL2 and the pinned layer PL20 may have the perpendicular magnetic anisotropy. Arrows indicated in the plurality of free layers FL2 and the pinned layer PL20 exemplarily show available magnetization directions of the plurality of free layers FL2 and the pinned layer PL20.

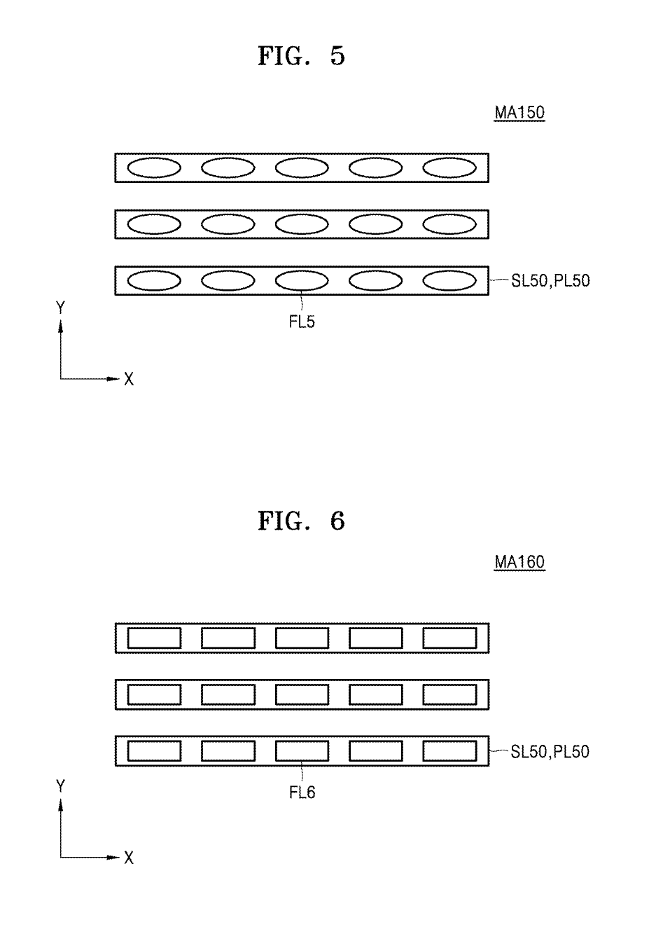

FIG. 3 is a cross-sectional view of a magnetoresistive structure having an in-plane magnetic anisotropy according to other example embodiments of the present inventive concepts.

Referring to FIG. 3, a magnetoresistive structure M130 may include a plurality of free layers FL3 and a separation layer SL30 and a pinned layer PL30 that cover the plurality of free layers FL3. The plurality of free layers FL3 and the pinned layer PL30 may have in-plane magnetic anisotropy. Arrows indicated in the plurality of free layers FL3 and the pinned layer PL30 exemplarily show available magnetization directions of the plurality of free layers FL3 and the pinned layer PL30.

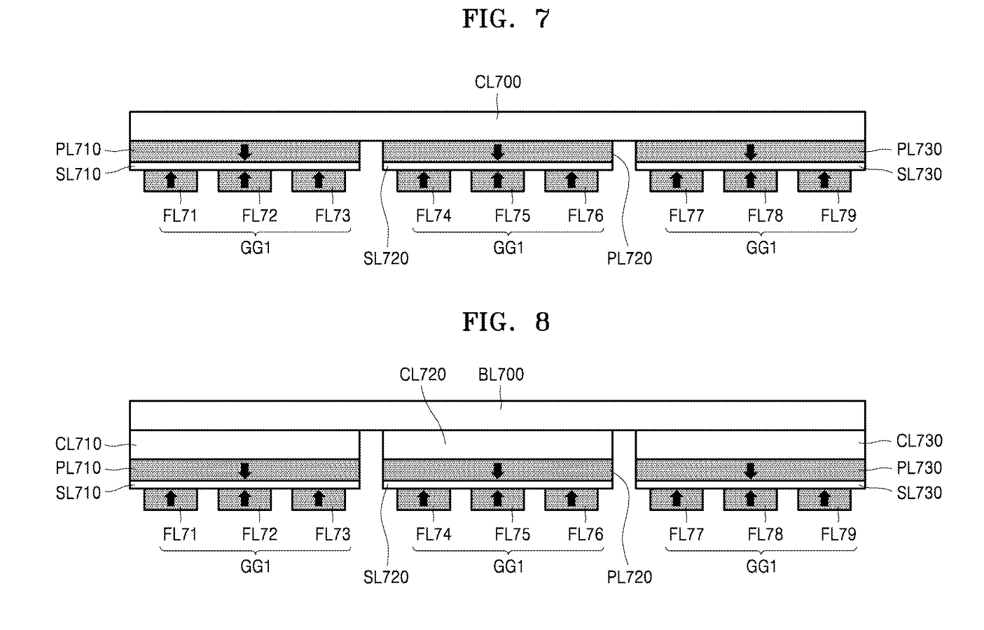

FIG. 4 is a cross-sectional view of a magnetoresistive structure according to yet other example embodiments of the present inventive concepts.

Referring to FIG. 4, a magnetoresistive structure M140 may include a plurality of free layers FL4 and a separation layer SL40 and a pinned layer PL40 that cover the plurality of free layers FL4. The plurality of free layers FL4 each may include a horizontal element n1 and at least one vertical element n2 protruding from the horizontal element n1 in a perpendicular direction. For example, a cross-section of each of the free layers FL4 may have an “n” shaped structure or a structure similar to the “n” shaped structure. The cross-section of each of the free layers FL4 may be shaped in the form of a protrusion. If the vertical element n2 is an element protruding from both ends of the horizontal element n1 with respect to a first direction, each of the free layers FL4 may further include another vertical element (not shown) protruding from both ends of the horizontal element n1 with respect to a second direction. The second direction may be a direction perpendicular to the first direction. In other words, if the vertical element n2 is an element protruding from both ends of the horizontal element n1 with respect to an X-axis direction, each of the free layers FL4 may further include another vertical element (not shown) protruding from both ends of the horizontal element n1 with respect to a Y-axis direction. In addition, locations and number of the vertical elements n2 may be modified in various ways. Although not shown, a non-magnetic material layer may be further disposed on a lower surface of the horizontal element n1 between the two vertical elements n2 in FIG. 4. The non-magnetic material layer may be formed of, for example, a metal.

As shown in FIG. 4, when the free layers FL4 each have a structure including the horizontal element n1 and the at least one vertical element n2, a thermal stability of the free layers FL4 may be enhanced. To change a magnetization direction of the horizontal element n1 of the free layers FL4, a magnetization direction of the vertical element n2 also needs to be changed. In this regard, the free layers FL4 may have the excellent thermal stability. When the size of the free layers FL3 of FIG. 3 is reduced, it may be more difficult to obtain the required thermal stability of the free layers FL3. However, by forming the free layers FL4 in the “n” shaped structure as shown in FIG. 4 or a similar structure thereto, the thermal stability of the free layers FL4 may be easily secured. The free layers FL4 having “n” shaped cross-sections as shown in FIG. 4 are not limited to free layers having in-plane magnetic anisotropy and may be also applied to free layers having perpendicular magnetic anisotropy. Further, the n″ shaped structure may be modified in various ways.

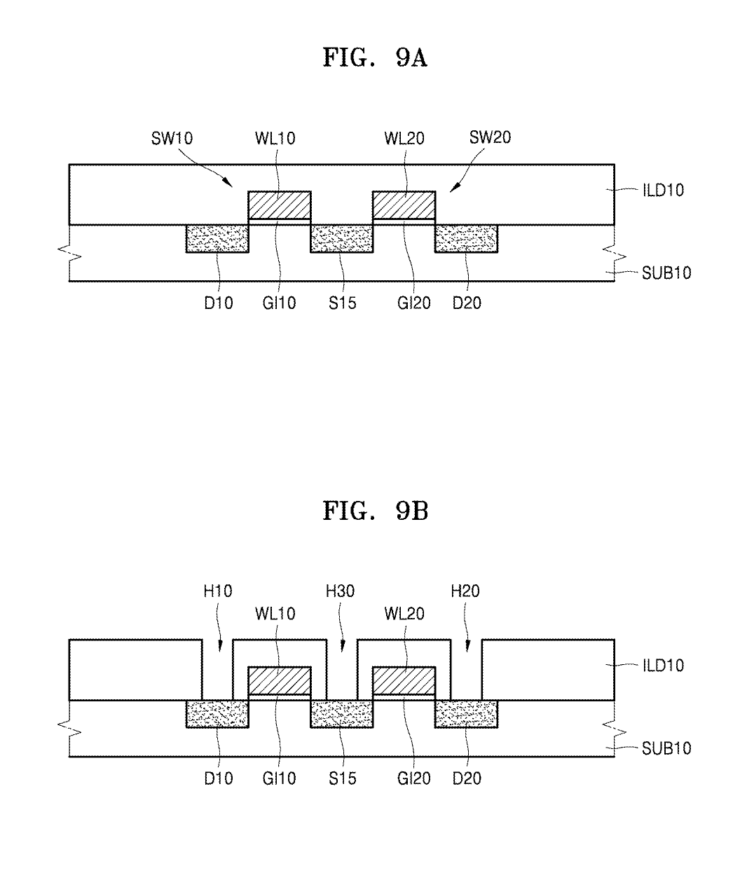

FIGS. 5 and 6 are plan views of magnetoresistive structure arrays according to further example embodiments of the present inventive concepts.

Referring to FIG. 5, a plurality of free layers FL5 may be arranged to be spaced apart from each other such that a magnetoresistive structure array MA150 is formed. The plurality of free layers FL5 may be arranged in a plurality of rows and columns. In this regard, although the plurality of free layers FL5 are arranged in 3 rows and 5 columns, this is just an example and the arrangement of the plurality of free layers FL5 may be modified in various ways. A separation layer SL50 and a pinned layer PL50 that cover each row of the plurality of free layers FL5 may be provided. The separation layer SL50 and the pinned layer PL50 may have line shapes. The free layers FL5 may have oval shapes having major axes in an X-axis direction.

Shapes of the free layers FL5 of FIG. 5 may be modified in various ways. An example is shown in FIG. 6. Referring to FIG. 6, free layers FL6 may have rectangular shapes and spaced apart from each other such that a magnetoresistive structure array MA160 is formed.

The plane structures of FIGS. 5 and 6 may be applied to the magnetoresistive structures M120, M130, and M140 of FIGS. 2, 3, and 4.

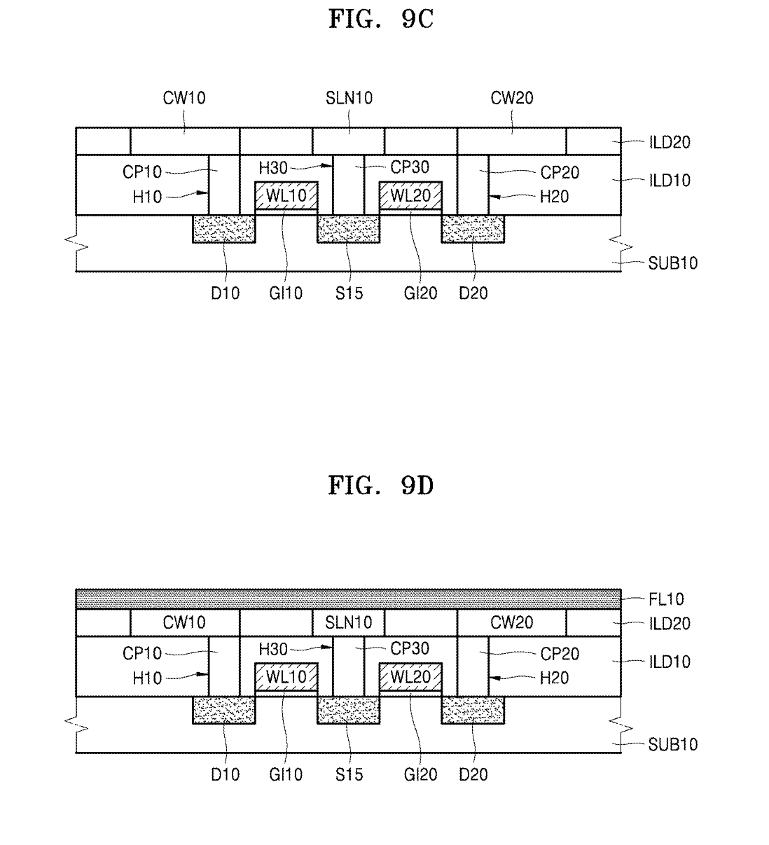

FIG. 7 is a cross-sectional view of a magnetoresistive structure according to still other example embodiments of the present inventive concepts.

In the present example embodiments, the magnetoresistive structure may include a plurality of separated pinned layers PL710, PL720, and PL730, and a plurality of free layers FL71 through FL73, FL74 through FL76, and FL77 through FL79 respectively corresponding to the pinned layers PL710, PL720, and PL730.

Referring to FIG. 7, a magnetoresistive structure may include the plurality of free layers FL71 through FL79 that may be divided into a plurality of groups GG1 through GG3. For example, the first group GG1 may include the first through third free layers FL71 through FL73, the second group GG2 may include the fourth through sixth free layers FL74 through FL76, and the third group GG3 may include the seventh through ninth free layers FL77 through FL79. The magnetoresistive structure may include a first separation layer SL710 and a first pinned layer PL710 that cover the first through third free layers FL71 through FL73 of the first group GG1, a second separation layer SL720 and a second pinned layer PL720 that cover the fourth through sixth free layers FL74 through FL76 of the second group GG2, and a third separation layer SL730 and a third pinned layer PL730 that cover the seventh through ninth free layers FL77 through FL79 of the third group GG3. In the present example embodiments, the magnetoresistive structure may include a capping layer CL700 that covers the plurality of pinned layers PL710, PL720, and PL730. The capping layer CL700 may be formed of a metal and may be used as a bit line. Alternatively, separately from the capping layer CL700, a bit line (not shown) may be provided on the capping layer CL700.

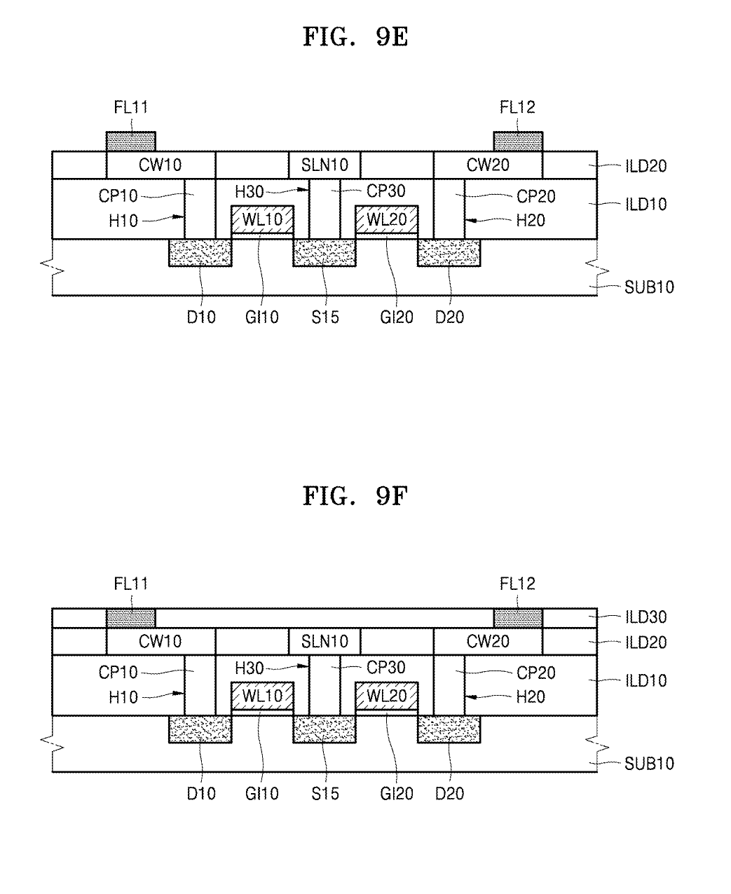

According to other example embodiments, in FIG. 7, the capping layer CL700 may be separated into a plurality of capping layers, and a bit line may be formed on the plurality of capping layers. An example is shown in FIG. 8.

Referring to FIG. 8, a magnetoresistive structure may include a plurality of capping layers CL710, CL720, and CL730 respectively corresponding to the pinned layers PL710, PL720, and PL730, and a bit line BL700 covering the capping layers CL710, CL720, and CL730. Each of the capping layers CL710, CL720, and CL730 may have the same plane structure as the respectively corresponding pinned layers PL710, PL720, and PL730.

The magnetoresistive structures according to the example embodiments of the present inventive concepts may be applied to a memory device (magnetic memory device). An example is shown in FIG. 1. The memory device 1000 of FIG. 1 may be MRAM. The MRAM may be spin transfer torque (STT)-MRAM. The STT-MRAM does not need a separate conductive line (i.e., a digit line) for generating an external magnetic field differently from an existing MRAM, thereby advantageously facilitating high integration and having a simple operation method. However, the magnetoresistive structure according to the present example embodiments may be applied to the existing MRAM as well as the STT-MRAM. Further, the magnetoresistive structure may be applied to other devices for various purposes as well as the memory device (MRAM).

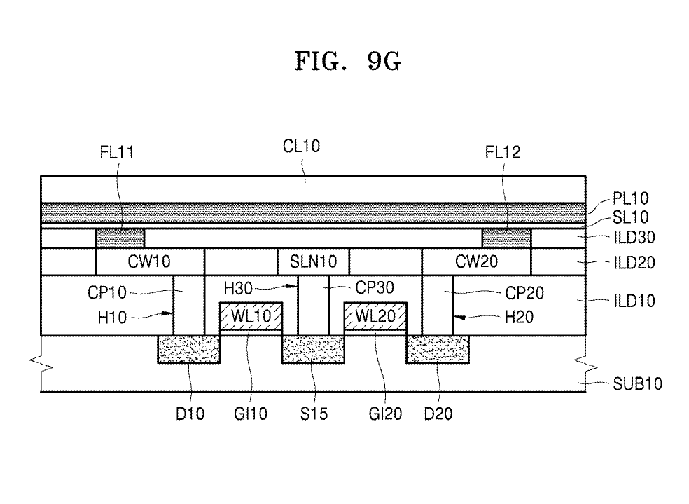

FIGS. 9A through 9G are cross-sectional views for explaining a method of manufacturing a memory device including a magnetoresistive structure according to some example embodiments of the present inventive concepts.

Referring to FIG. 9A, first and second drain regions D10 and D20 and a common source region S15 may be formed on a substrate SUB10. The common source region S15 may be formed between the first and second drain regions D10 and D20. A first word line WL10 may be formed on the substrate SUB10 between the first drain region D10 and the common source region S15. A first gate insulating layer GI10 may be formed between the substrate SUB10 and the first word line WL10. A second word line WL20 may be formed on the substrate SUB10 between the second drain region D20 and the common source region S15. A second gate insulating layer GI20 may be formed between the substrate SUB10 and the second word line WL20. The first drain region D10, the common source region S15, and the first word line WL10 may form a first switching element SW10. The second drain region D20, the common source region S15, and the second word line WL20 may form a second switching element SW20. Thereafter, a first insulating layer ILD10 covering the first and second switching elements SW10 and SW20 may be formed on the substrate SUB10. That is, the first insulating layer ILD10 covering the first and second drain regions D10 and D20, the common source region S15, and the first and second word lines WL10 and WL20 may be formed on the substrate SUB10.

Referring to FIG. 9B, first through third contact holes H10 through H30 may be formed by etching portions of the first insulating layer ILD10. The first contact hole H10 may expose the first drain region D10, the second contact hole H20 may expose the second drain region D20, and the third contact hole H30 may expose the common source region S15.

Referring to FIG. 9C, first through third contact plugs CP10 through CP30 may be formed in the first through third contact holes H10 through H30. Thereafter, a first connection wire CW10, a second connection wire CW20, and a source line SLN10 may be formed on the first insulating layer ILD10. The first connection wire CW10 may contact the first contact plug CP10. The second connection wire CW20 may contact the second contact plug CP20. The source line SLN10 may contact the third contact plug CP30. Thereafter, a second insulating layer ILD20 having a height that is equal to (or approximately equal to) that of the first connection wire CW10, the second connection wire CW20, and the source line SLN10 may be formed therearound.

Referring to FIG. 9D, a first magnetic layer FL10 covering the second insulating layer ILD20 and the first connection wire CW10, and the second connection wire CW20 and the source line SLN10 may be formed.

Referring to FIG. 9E, a plurality of free layers FL11 and FL12 may be formed by etching (patterning) the first magnetic layer FL10. The plurality of free layers FL11 and FL12 may include a first free layer FL11 and a second free layer FL12. The first free layer FL11 may be formed on the first connection wire CW10. The second free layer FL12 may be formed on the second connection wire CW20. The first free layer FL11 may be electrically connected to the first drain region D10 via the first connection wire CW10 and the first contact plug CP10. Similarly, the second free layer FL12 may be electrically connected to the second drain region D20 via the second connection wire CW20 and the second contact plug CP20.

Referring to FIG. 9F, a third insulating layer ILD30 having a height that is the same as (or similar to) the plurality of free layers FL11 and FL12 may be formed therearound.

Referring to FIG. 9G, a separation layer SL10 and a pinned layer PL10 that cover the plurality of free layers FL11 and FL12 may be formed on the third insulating layer ILD30. The separation layer SL10 and the pinned layer PL10 may be formed by sequentially depositing a separation layer material (an insulating layer or a conductive layer) and a pinned layer material (a second magnetic layer) and concurrently patterning the separation layer material and the pinned layer material in desired (or, predetermined) shapes (for example, line shapes). Thus, the separation layer SL10 and the pinned layer PL10 may have structures as shown in FIGS. 5 and 6. If necessary, a capping layer CL10 may be further formed on the pinned layer PL10. The capping layer CL10 may be formed of a desired (or, predetermined) non-magnetic material, for example, a metal material. The capping layer CL10 may be formed to have a plane structure that is the same as (or almost the same) as that of the pinned layer PL10. The separation layer SL10, the pinned layer PL10, and the capping layer CL10 may be formed by using a single etch mask. Although not shown, a bit line may be further formed on the capping layer CL10. The bit line may also have a plane structure that is the same as (or almost the same) as that of the pinned layer PL10. In FIG. 9G, the plurality of free layers FL11 and FL12, the separation layer SL10, and the pinned layer PL10 may form a “magnetoresistive structure”. The first free layer FL11, a region of the separation layer SL10 and a region of the pinned layer PL10 that correspond to the first free layer FL11 may form a “first cell region” in the magnetoresistive structure. Similarly, the second free layer FL12, a region of the separation layer SL10 and a region of the pinned layer PL10 that correspond to the second free layer FL12 may form a “second cell region” in the magnetoresistive structure.

Although the method of manufacturing the magnetoresistive structure M100 and the memory device 1000 including the magnetoresistive structure M100 of FIG. 1 is explained in relation to FIGS. 9A through 9G, the magnetoresistive structure and the memory device including the magnetoresistive structure of FIGS. 2 through 8 may be manufactured by modifying the method. This modification is well understood by one of ordinary skill in the art, and thus, a detailed description thereof is omitted.

While the inventive concepts have been particularly shown and described with reference to the embodiments thereof, it should not be construed as being limited to these embodiments that should be considered only an example. It will be understood by those of ordinary skill in the art that the magnetoresistive structures and structures of the memory devices of FIGS. 1 through 8 may be modified in various ways. As a specific example, it will be understood by those of ordinary skill in the art that a separation layer and/or a pinned layer may be patterned to have greater widths than a single free layer, and may not cover a plurality of free layers. It will be also understood by those of ordinary skill in the art that the magnetoresistive structure may include at least one layer other than the plurality of free layers, the separation layer, and the pinned layer. It will be also understood by those of ordinary skill in the art that structures of the switching elements may be modified in various ways. In addition, it will be understood by those of ordinary skill in the art that the magnetoresistive structures according to example embodiments of the present inventive concepts may be applied to the memory device of FIG. 1, another memory device having a different structure, or another magnetic device other than a memory device. Furthermore, it will be understood that the method described with reference to FIGS. 9A through 9G may be modified in various ways. Therefore, the scope of example embodiments of the inventive concepts is defined not by the detailed description of example embodiments of the inventive concepts but by the appended claims.

What is claimed is:

1. A magnetoresistive structure, comprising:
a plurality of free layers each having a magnetization direction that is changeable;
a separation layer covering at least two of the plurality of free layers; and
a pinned layer opposing the plurality of free layers, the pinned layer having a magnetization direction that is fixed,
wherein the separation layer is between the pinned layer and the plurality of free layers.

2. The magnetoresistive structure of claim 1, wherein both side surfaces of the separation layer are spaced apart from the plurality of free layers.

3. The magnetoresistive structure of claim 1, wherein
the separation layer is on the plurality of free layers, and
the pinned layer is on the separation layer.

4. The magnetoresistive structure of claim 1, wherein the separation layer and the pinned layer have a same plane structure.

5. The magnetoresistive structure of claim 1, wherein the plurality of free layers and the pinned layer have perpendicular magnetic anisotropy.

6. The magnetoresistive structure of claim 1, wherein the plurality of free layers and the pinned layer have in-plane magnetic anisotropy.

7. The magnetoresistive structure of claim 6, wherein each of the plurality of free layers includes a horizontal element and at least one vertical element extending from the horizontal element.

8. The magnetoresistive structure of claim 1, wherein
a plurality of separation layers are provided, and spaced apart from each other in plan view, and
at least two of the plurality of free layers correspond to a respective one of the plurality of separation layers.

9. The magnetoresistive structure of claim 1, wherein
a plurality of pinned layers are provided, and spaced apart from each other, and
at least two of the plurality of free layers correspond to a respective one of the plurality of pinned layers.

10. A memory device, comprising:
the magnetoresistive structure according to claim 1.

11. The memory device of claim 10, wherein the memory device is spin transfer torque magnetic random access memory (STT-MRAM).

12. A magnetoresistive structure, comprising:
a plurality of free layers each having a magnetization direction that is changeable;
a pinned layer shared by at least two of the plurality of free layers, wherein the pinned layer has a magnetization direction that is fixed; and
at least one separation layer between the plurality of free layers and the pinned layer.

13. The magnetoresistive structure of claim 12, wherein the magnetoresistive structure has a top-pinned structure in which the pinned layer is above the plurality of free layers.

14. The magnetoresistive structure of claim 12, wherein the plurality of free layers and the pinned layer have perpendicular magnetic anisotropy.

15. The magnetoresistive structure of claim 12, wherein the plurality of free layers and the pinned layer have in-plane magnetic anisotropy.

16. A memory device, comprising:
the magnetoresistive structure according to claim 12.

17. A magnetoresistive structure, comprising:
a stacked structure including a separation layer and a pinned layer, sequentially stacked, wherein the pinned layer has a magnetization direction that is fixed; and
a plurality of free layers under the stacked structure, the plurality of free layers each having a magnetization direction that is changeable,
wherein the plurality of free layers are each coupled with the pinned layer via the separation layer.

18. The magnetoresistive structure of claim 17, wherein the plurality of free layers and the pinned layer have a same magnetic anisotropy.

19. The magnetoresistive structure of claim 17, wherein
each of the plurality of free layers has a main body and at least one protrusion protruding from the main body, and
the at least one protrusion protrudes in a direction perpendicular to an upper surface of the main body.

20. The magnetoresistive structure of claim 17, wherein both ends of the stacked structure project beyond ends of the plurality of free layers in a direction parallel with an upper surface of the plurality of free layers.
